(19) United States
(12) Patent Application Publication
(10) Pub. No.: US 2025/0277310 A1
(43) Pub. Date: Sep. 4, 2025

(54) APPARATUS FOR MANUFACTURING DISPLAY APPARATUS

(71) Applicant: Samsung Display Co., LTD., Yongin-si (KR)

(72) Inventor: Sungmin HUCH, Yongin-si (KR)

(21) Appl. No.: 18/912,984

(22) Filed: Oct. 11, 2024

(30) Foreign Application Priority Data
Mar. 4, 2024 (KR) 10-2024-0030911

(51) Int. Cl. C23C 16/52; C23C 16/44; C23C 16/455; C23C 16/50; H10K 71/10

(52) U.S. Cl. CPC C23C 16/52; C23C 16/4401; C23C 16/45536; C23C 16/45544; C23C 16/50; H10K 71/10

(57) ABSTRACT

An apparatus for manufacturing a display apparatus includes a process portion including a plurality of deposition portions which perform a deposition process of depositing a deposition material on a display substrate and a cleaning process of cleaning an inside, and a controller which controls the process portion.

This application claims priority to Korean Patent Application No. 10-2024-0030911, filed on Mar. 4, 2024, and all the benefits accruing therefrom under 35 U.S.C. § 119, the content of which in its entirety is herein incorporated by reference.

### BACKGROUND

### 1. Field

Embodiments relate to an apparatus, and more particularly, to an apparatus for manufacturing a display apparatus.

### 2. Description of the Related Art

Mobile electronic apparatuses are widely used. As mobile electronic apparatuses, recently, tablet personal computers are being widely used as well as miniaturized electronic apparatuses such as mobile phones.

To support various functions, e.g., to provide a user with visual information, such as images, the mobile electronic apparatuses include a display apparatus. Recently, as the parts which drive a display apparatus are being miniaturized, the proportion of the display apparatus in an electronic apparatus is gradually increased and a structure that may be bent to form a preset angle from a flat state is also under development.

In a process of manufacturing the display apparatus, a deposition process of a deposition portion depositing a deposition material on a substrate is desired. In addition, a cleaning process of cleaning the inside of the deposition portion at a preset period is also desired.

### SUMMARY

Embodiments include generating a schedule of each of a plurality of deposition portions such that the number of deposition portions performing a cleaning process simultaneously is reduced.

However, such a technical feature is just an example, and the disclosure is not limited thereto.

Additional features will be set forth in part in the description which follows and, in part, will be apparent from the description, or may be learned by practice of the presented embodiments of the disclosure.

In an embodiment of the disclosure, an apparatus for manufacturing a display apparatus includes a process portion including a plurality of deposition portions which perform a deposition process of depositing a deposition material on a display substrate, and a cleaning process of cleaning an inside of the plurality of deposition portions, and a controller which controls the process portion. The controller includes an initial scheduler which generates an initial schedule such that each of the plurality of deposition portions performs the deposition process A times (A is a natural number) and then performs the cleaning process once, a determining portion which determines whether the initial schedule satisfies a first condition that a number of deposition portions simultaneously performing the cleaning process is B or less (B is a natural number, an executer which, when the initial schedule satisfies the first condition, operates the plurality of deposition portions based on the initial schedule, and a modifier which, when the initial schedule does not satisfy the first condition, modifies the initial schedule to a first modified schedule such that one of the plurality of deposition portions simultaneously performing the cleaning process performs the deposition process (A-1) times and then performs the cleaning process once.

In an embodiment, the determining portion may determine whether the first modified schedule satisfies the first condition, and the executer may, when the first modified schedule satisfies the first condition, operate the plurality of deposition portions based on the first modified schedule.

In an embodiment, the modifier may, when the initial schedule does not satisfy the first condition, modify the initial schedule to the first modified schedule such that another of the plurality of deposition portions simultaneously performing the cleaning process performs the deposition process (A-2) times and then performs the cleaning process once.

In an embodiment, A may be about 7.

In an embodiment, B may be about 2.

In an embodiment, the plurality of deposition portions may be provided as eight.

In an embodiment of the disclosure, an apparatus for manufacturing a display apparatus includes a first process portion including a plurality of first deposition portions which perform a deposition process of depositing a deposition material on a display substrate, and a cleaning process of cleaning an inside, a second process portion including a plurality of second deposition portions which perform the deposition process of depositing the deposition material on the display substrate, and the cleaning process of cleaning the inside, and a controller including a first controller which controls the first process portion and a second controller which controls the second process portion. The first controller includes a first initial scheduler which generates a first initial schedule such that each of the plurality of first deposition portions performs the deposition process A times (A is a natural number) and then performs the cleaning process once, a first determining portion which determines whether the first initial schedule satisfies a first-1 condition that a number of first deposition portions simultaneously performing the cleaning process is B or less (B is a natural number), a first executer which, when the first initial schedule satisfies the first-1 condition, operates the plurality of first deposition portions based on the first initial schedule, and a first modifier which, when the first initial schedule does not satisfy the first-1 condition, modifies the first initial schedule to a first-1 modified schedule such that one of the plurality of first deposition portions simultaneously performing the cleaning process performs the deposition process (A-1) times and then performs the cleaning process once.

In an embodiment, the first determining portion may determine whether the first-1 modified schedule satisfies the first-1 condition, and the first executer may, when the first-1 modified schedule satisfies the first-1 condition, operates the plurality of first deposition portions based on the first modified schedule.

In an embodiment, A may be about 7.

In an embodiment, B may be about 1.

In an embodiment, the plurality of first deposition portions may be provided as five.

In an embodiment, the second controller may include a second initial scheduler which generates a second initial schedule such that each of the plurality of second deposition portions performs the deposition process A times (A is a natural number) and then performs the cleaning process once, a second determining portion which determines whether the second initial schedule satisfies a first-2 condition that a number of second deposition portions simultaneously performing the cleaning process is B or less (B is a natural number, a second executer which, when the second initial schedule satisfies the first-2 condition, operates the plurality of second deposition portions based on the second initial schedule, and a second modifier which, when the second initial schedule does not satisfy the first-2 condition, modifies the second initial schedule to a second-1 modified schedule such that one of the plurality of second deposition portions simultaneously performing the cleaning process performs the deposition process (A-1) times and then performs the cleaning process once.

In an embodiment, the second determining portion may determine whether the second-1 modified schedule satisfies the first-2 condition, and the second executer may, when the second-2 modified schedule satisfies the first-1 condition, operates the plurality of second deposition portions based on the second-1 modified schedule.

In an embodiment, the plurality of second deposition portions may be provided as five.

In an embodiment, the deposition process of the display substrate may be performed by one of the plurality of first deposition portions and the plurality of second deposition portions.

These and/or other features will become apparent and more readily appreciated from the following detailed description of the embodiments, the accompanying drawings, and claims.

### BRIEF DESCRIPTION OF THE DRAWINGS

The above and other features and advantages of illustrative embodiments of the disclosure will be more apparent from the following description taken in conjunction with the accompanying drawings, in which:

FIG. 1 is a schematic plan view of an embodiment of an apparatus for manufacturing a display apparatus;

FIG. 2 is a schematic cross-sectional view of an embodiment of a deposition portion;

FIG. 3 is a block diagram of an embodiment of a controller;

FIG. 4 is a flowchart showing an embodiment of a method of manufacturing a display apparatus;

FIG. 5 is a view of an embodiment of an initial schedule;

FIG. 6 is a view of an embodiment of a first modified schedule;

FIG. 7 is a schematic plan view of an embodiment of an apparatus for manufacturing a display apparatus;

FIG. 8 is a block diagram of an embodiment of a controller;

FIG. 9 is a flowchart showing an embodiment of a method of manufacturing a display apparatus;

FIG. 10 is a schematic plan view of an embodiment of a display apparatus;

FIG. 11 is a schematic cross-sectional view of an embodiment of a display apparatus; and

FIG. 12 is an equivalent circuit diagram of an embodiment of a pixel of a display apparatus.

### DETAILED DESCRIPTION

Reference will now be made in detail to embodiments, illustrative embodiments of which are illustrated in the accompanying drawings, where like reference numerals refer to like elements throughout. In this regard, the illustrated embodiments may have different forms and should not be construed as being limited to the descriptions set forth herein. Accordingly, the embodiments are merely described below, by referring to the drawing figures, to explain features of the description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, illustrative embodiments will be illustrated in the drawings and described in the written description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described with reference to the accompanying drawings, where like reference numerals refer to like elements throughout and a repeated description thereof is omitted.

While such terms as “first” and “second” may be used to describe various elements, such elements must not be limited to the above terms. The above terms are used to distinguish one element from another.

The singular forms “a,” “an,” and “the” as used herein are intended to include the plural forms as well unless the context clearly indicates otherwise.

It will be understood that the terms “comprise,” “comprising,” “include” and/or “including” as used herein specify the presence of stated features or elements but do not preclude the addition of one or more other features or elements.

It will be further understood that, when a layer, region, or element is referred to as being “on” another layer, region, or element, it may be directly or indirectly on the other layer, region, or element. That is, for example, intervening layers, regions, or elements may be present.

Sizes of elements in the drawings may be exaggerated or reduced for convenience of explanation. As an example, the size and thickness of each element shown in the drawings are arbitrarily represented for convenience of description, and thus, the disclosure is not necessarily limited thereto.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different orientations that are not perpendicular to one another.

In the case where an illustrative embodiment may be implemented differently, a specific process order may be performed in the order different from the described order. As an example, two processes successively described may be simultaneously performed substantially and performed in the opposite order.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within ±30%, 20%, 10%, 5% of the stated value, for example.

The term “controller” as used herein is intended to mean a hardware component that performs a predetermined function. The hardware component may include a circuitry such as a field-programmable gate array (“FPGA”) or an application-specific integrated circuit (“ASIC”), for example.

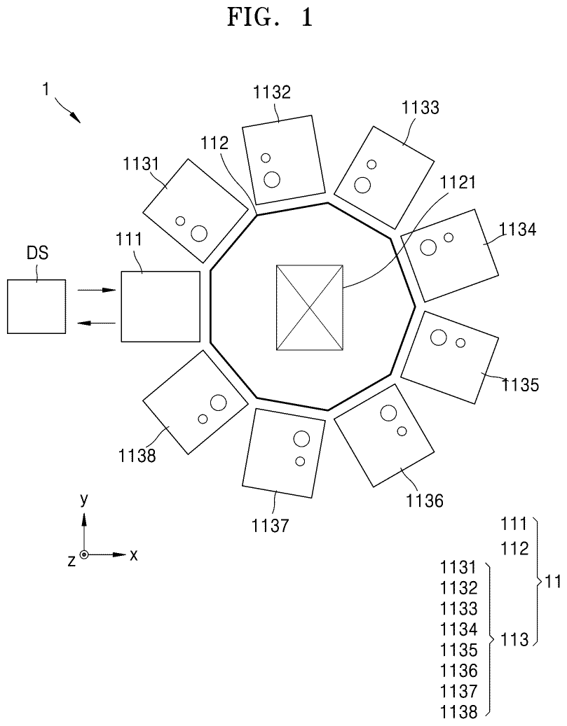

FIG. 1 is a schematic plan view of an embodiment of an apparatus 1 for manufacturing a display apparatus.

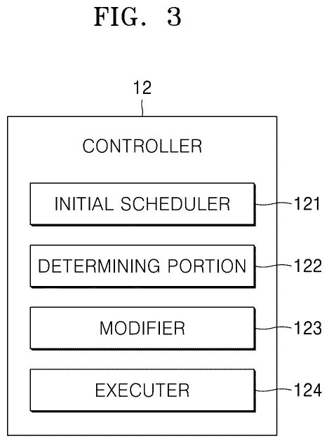

Referring to FIG. 1, the apparatus 1 for manufacturing a display apparatus may include a process portion 11 and a controller (e.g., 12 in FIG. 3). Specifically, the process portion 11 may include a loading portion 111, a carry portion 112, and a deposition portion 113.

The loading portion 111 may serve as an entry of the apparatus 1 for manufacturing a display apparatus, and a display substrate DS may be loaded into the loading portion 111 from the outside. The loading portion 111 may be connected to the carry portion 112. The display substrate DS may be transferred to the carry portion 112 through the loading portion 111.

The inner pressure of the loading portion 111 may be adjusted to be equal or similar to atmospheric pressure. In an alternative embodiment, the inner pressure of the loading portion 111 may be adjusted to be equal or similar to a vacuum state. In an embodiment, when the display substrate DS is loaded from the outside, the pressure of the loading portion 111 may be adjusted to be equal or similar to atmospheric pressure. In addition, when the display substrate DS is transferred to the carry portion 112, the pressure of the loading portion 111 may be adjusted to be equal or similar to a vacuum state.

The carry portion 112 may be connected to the loading portion 111 and the deposition portion 113. The carry portion 112 may receive or transfer the display substrate DS from the deposition portion 113 or the loading portion 111. In this case, the carry portion 112 may include a robot arm 1121. The robot arm 1121 may transfer the display substrate DS from the loading portion 111 to the carry portion 112. In addition, the robot arm 1121 may transfer the display substrate DS from the carry portion 112 to the deposition portion 113, or transfer a process-completed display substrate DS from the deposition portion 113 to the carry portion 112.

The deposition portion 113 may perform a deposition process and a cleaning process. The deposition process may be a process of depositing a deposition material on the display substrate DS. The cleaning process may be a process of cleaning the inside of the deposition portion 113. The deposition portion 113 may be provided in plural. The plurality of deposition portions 113 may perform the same deposition process. Accordingly, the deposition material may be deposited on the display substrate DS by one of the plurality of deposition portions 113. The deposition portion 113 may be connected to the carry portion 112. That is, each of the plurality of deposition portions 113 may be connected to the carry portion 112.

In an embodiment, eight deposition portions 113 may be provided. In an embodiment, the plurality of deposition portions 113 may include a first-1 deposition portion 1131, a first-2 deposition portion 1132, a first-3 deposition portion 1133, a first-4 deposition portion 1134, a first-5 deposition portion 1135, a first-6 deposition portion 1136, a first-7 deposition portion 1137, and a first-8 deposition portion 1138. The plurality of deposition portions 113 may surround the carry portion 112 and be arranged in a circumferential direction. The plurality of deposition portions 113 may be arranged within a radius range of the robot arm 1121. However, this is provided as one of embodiments and the number and arrangement of the deposition portions 113 are not limited thereto.

The deposition process for manufacturing the display apparatus may be performed by the deposition portion 113. In an embodiment, chemical vapor deposition (“CVD”) may be performed within the deposition portion 113. In another embodiment, plasma enhanced chemical vapor deposition (“PECVD”) may be performed within the deposition portion 113. In another embodiment, atomic layer deposition (“ALD”) or plasma enhanced atomic layer deposition (“PEALD”) may be performed within the deposition portion 113.

Here, the display substrate DS may be a display apparatus being manufactured. The display substrate DS may include glass or include polymer resin such as polyethersulfone, polyarylate, polyetherimide, polyethylene naphthalate, polyethylene terephthalate, polyphenylene sulfide, polyimide, polycarbonate, cellulose tri acetate (“TAC”), cellulose acetate propionate, or the like.

In an embodiment, the display substrate DS may be a mother substrate, which is a set of cell areas. In this case, each cell area may be a display apparatus being manufactured. The display substrate DS may be separated by a cutting process. In an embodiment, the display substrate DS may be separated into a plurality of partial substrates. In an embodiment, the partial substrate may be a substrate in which the display substrate DS is divided into two halves. In an alternative embodiment, the display substrate DS may be separated along the cell areas. In an embodiment, the entirety of the display substrate DS may be a display apparatus being manufactured.

In an embodiment, the display substrate DS may be laser-cut by a laser apparatus. In another embodiment, the display substrate DS may be cut by a knife.

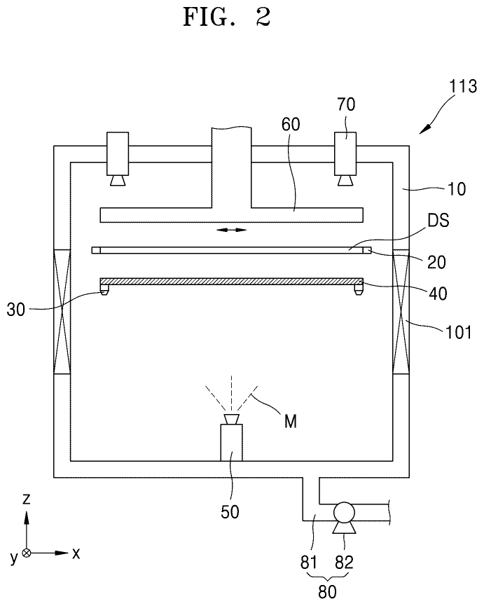

The controller may control the process portion 11. In an embodiment, the controller may control each of the plurality of deposition portions 113. The controller is described below in detail with reference to FIGS. 2 to 6.

A process in which the deposition material is deposited on the display substrate DS is described. The display substrate DS may be loaded to the loading portion 111 from the outside. The display substrate DS loaded into the loading portion 111 may be transferred to the carry portion 112. The carry portion 112 may transfer the display substrate DS to one of the plurality of deposition portions 113. When the deposition process of the display substrate DS is completed at one of the plurality of deposition portions 113, the carry portion 112 may receive the display substrate DS again. The deposition process-completed display substrate DS may be carried to the outside through the loading portion 111.

FIG. 2 is a schematic cross-sectional view of an embodiment of the deposition portion 113.

The deposition portion 113 may include a chamber 10, a first supporter 20, a second supporter 30, a mask assembly 40, a deposition source 50, a magnetic force portion 60, a vision portion 70, and a pressure adjuster 80.

A space may be defined inside the chamber 10. The display substrate DS and the mask assembly 40 may be received in the space. In this case, a portion of the chamber 10 may be open. A gate valve 101 may be installed in the open portion of the chamber 10. In this case, the open portion of the chamber 10 may be opened or closed according to an operation of the gate valve 101.

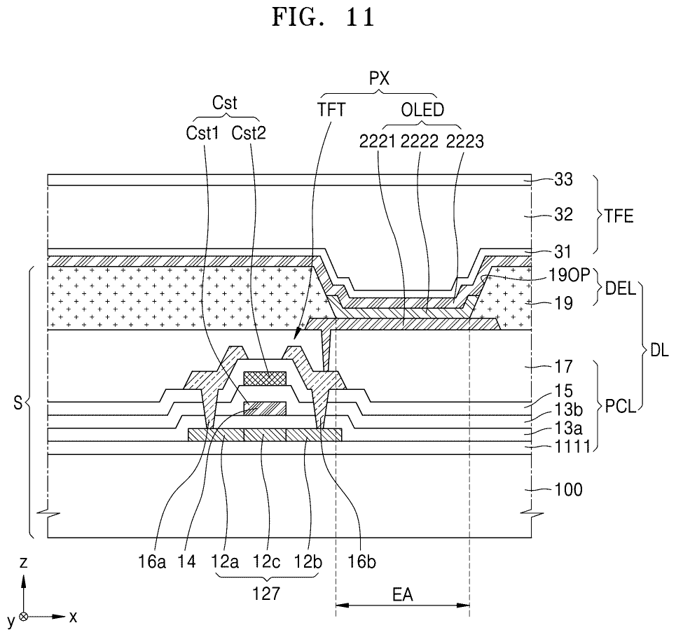

In this case, the display substrate DS may denote the display substrate DS in which at least one of an organic layer, an inorganic layer, and a metal layer is deposited on a substrate 100 (refer to FIG. 11) described below, while the display apparatus is manufactured. In an alternative embodiment, the display substrate DS may be the substrate 100 (refer to FIG. 11) on which any of the organic layer, the inorganic layer, and the metal layer is not yet deposited.

The first supporter 20 may support the display substrate DS. In this case, the first supporter 20 may be a plate form fixed inside the chamber 10. In another embodiment, the first supporter 20 may be a shuttle form in which the display substrate DS is disposed (e.g., seated) and which is linearly movable inside the chamber 10. In another embodiment, the first supporter 20 may include an electrostatic chuck or an adhesive chuck disposed in the chamber 10 to be fixed or movable inside the chamber 10.

The second supporter 30 may support the mask assembly 40. In this case, the second supporter 30 may be disposed inside the chamber 10. The second supporter 30 may fine-adjust the position of the mask assembly 40. In this case, the second supporter 30 may include a driver, an alignment unit, or the like separately to move the mask assembly 40 in different directions.

In another embodiment, the second supporter 30 may be a shuttle form. In this case, the mask assembly 40 may be disposed (e.g., seated) on the second supporter 30. The second supporter 30 may transfer the mask assembly 40. In an embodiment, the second supporter 30 may move to the outside of the chamber 10, and after the mask assembly 40 is disposed (e.g., seated) on the second supporter 30, the second supporter 30 may enter the chamber 10 from the outside of the chamber 10.

In this case, the first supporter 20 may be unitary with the second supporter 30. In this case, the first supporter 20 and the second supporter 30 may include a movable shuttle. In this case, the first supporter 20 and the second supporter 30 may include a structure which fixes the mask assembly 40 to the display substrate DS with the display substrate DS disposed (e.g., seated) on the mask assembly 40, and may linearly move the display substrate DS and the mask assembly 40 simultaneously.

Hereinafter, for convenience of description, a form in which the first supporter 20 and the second supporter 30 are discriminated from each other and disposed in different positions, and a form in which the first supporter 20 and the second supporter 30 are disposed inside the chamber 10, are mainly described in detail.

The mask assembly 40 may be disposed to face the display substrate DS inside the chamber 10. A deposition material M may pass through the mask assembly 40 and be deposited on the display substrate DS.

The deposition source 50 may be disposed to face the mask assembly 40 and may supply the deposition material M such that the deposition material M passes through a deposition area of the mask assembly 40 and is deposited on the display substrate DS. In this case, the deposition source 50 may evaporate or sublimate the deposition material M by applying heat to the deposition material M. The deposition source 50 may be fixed inside the chamber 10, or disposed inside the chamber 10 to be linearly moved in one direction.

The magnetic force portion 60 may be disposed inside the chamber 10 to face the display substrate DS and/or the mask assembly 40. In this case, the magnetic force portion 60 may apply magnetic force to the mask assembly 40 and press the mask assembly 40 toward the display substrate DS. Particularly, the magnetic force portion 60 may not only prevent sagging of the mask assembly 40 but also allow the mask assembly 40 to be adjacent to the display substrate DS. In addition, the magnetic force portion 60 may maintain a uniform interval between the mask assembly 40 and the display substrate DS.

The vision portion 70 may be disposed in the chamber 10 and may capture the positions of the display substrate DS and the mask assembly 40. In this case, the vision portion 70 may include a camera which captures the display substrate DS and the mask assembly 40. The positions of the display substrate DS and the mask assembly 40 may be determined based on the images captured by the vision portion 70, and the transformation of the mask assembly 40 may be determined. In addition, the first supporter 20 may fine-adjust the position of the display substrate DS or the second supporter 30 may fine-adjust the position of the mask assembly 40 based on the captured images. Hereinafter, the case where the second supporter 30 fine-adjusts the position of the mask assembly 40 and aligns the positions of the display substrate DS and the mask assembly 40, is mainly described in detail.

The pressure adjuster 80 may be connected to the chamber 10 and may adjust the inner pressure of the chamber 10. In an embodiment, the pressure adjuster 80 may adjust the inner pressure of the chamber 10 to be equal or similar to atmospheric pressure. In addition, the pressure adjuster 80 may adjust the inner pressure of the chamber 10 to be equal or similar to a vacuum state.

The pressure adjuster 80 may include a connection pipe 81 and a pump 82. The connection pipe 81 is connected to the chamber 10, and the pump 82 is installed to the connection pipe 81. In this case, external air may be introduced through the connection pipe 81 or a gas inside the chamber 10 may be guided to the outside through the connection pipe 81 according to an operation of the pump 82.

A method of manufacturing the display apparatus by the deposition portion 113, is described. First, the display substrate DS may be prepared.

The pressure adjuster 80 may maintain the inside of the chamber 10 at a state equal or similar to atmospheric pressure. The gate valve 101 may operate to open the open portion of the chamber 10.

Then, the display substrate DS may be loaded into the inside of the chamber 10 from the outside. In this case, the display substrate DS may be loaded into the chamber 10 in various methods. In an embodiment, the display substrate DS may be loaded into the inside of the chamber 10 from the outside of the chamber 10 by a robot arm disposed outside the chamber 10. In another embodiment, in the case where the first supporter 20 is formed in a shuttle form, the first supporter 20 may be carried from the inside of the chamber 10 to the outside of the chamber 10, then, the display substrate DS may be disposed (e.g., seated) on the first supporter 20 by a separate robot arm disposed outside the chamber 10, and the first supporter 20 may be loaded into the inside of the chamber 10 from the outside of the chamber 10.

The mask assembly 40 may be disposed inside the chamber 10 as described above. In another embodiment, in the same manner as or similar manner to the display substrate DS, the mask assembly 40 may be loaded into the inside of the chamber 10 from the outside of the chamber 10.

When the display substrate DS is loaded into the inside of the chamber 10, the display substrate DS may be disposed (e.g., seated) on the first supporter 20. In this case, the vision portion 70 may capture the positions of the display substrate DS and the mask assembly 40. The positions of the display substrate DS and the mask assembly 40 may be determined based on images captured by the vision portion 70. In this case, the deposition portion 113 may include a separate controller (not shown) to determine the positions of the display substrate DS and the mask assembly 40.

When the determination of the positions of the display substrate DS and the mask assembly 40 is completed, the second supporter 30 may fine-adjust the position of the mask assembly 40.

Then, the deposition source 50 operates to supply the deposition material M toward the mask assembly 40, and the deposition material M passing through a plurality of pattern holes of the mask assembly 40 may be deposited on the display substrate DS. In this case, the deposition source 50 may move in parallel to the display substrate DS and the mask assembly 40, or the display substrate DS and the mask assembly 40 may move in parallel to the deposition source 50. That is, the deposition source 50 may move relative to the display substrate DS and the mask assembly 40. In this case, the pump 82 may maintain the pressure of the chamber 10 at a state equal or similar to vacuum by sucking in the gas inside the chamber 10 and discharging the gas to the outside.

As described above, the deposition material M supplied from the deposition source 50 may pass through the mask assembly 40, be deposited on the display substrate DS, and thus, form at least one of a plurality of layers, e.g., an organic layer, an inorganic layer, and a metal layer stacked in the display apparatus described below.

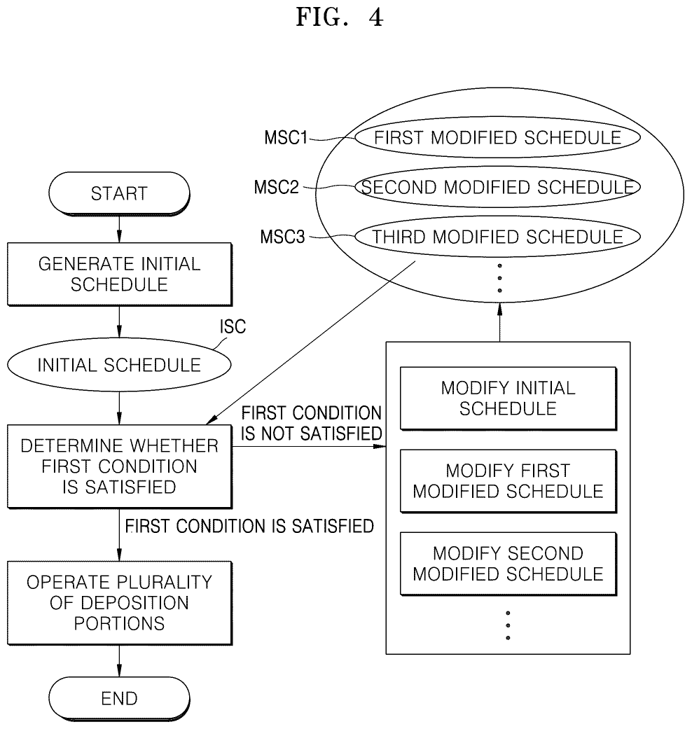

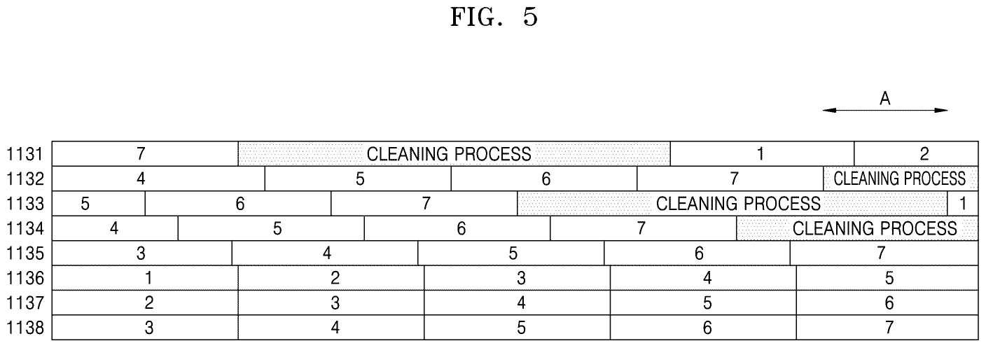

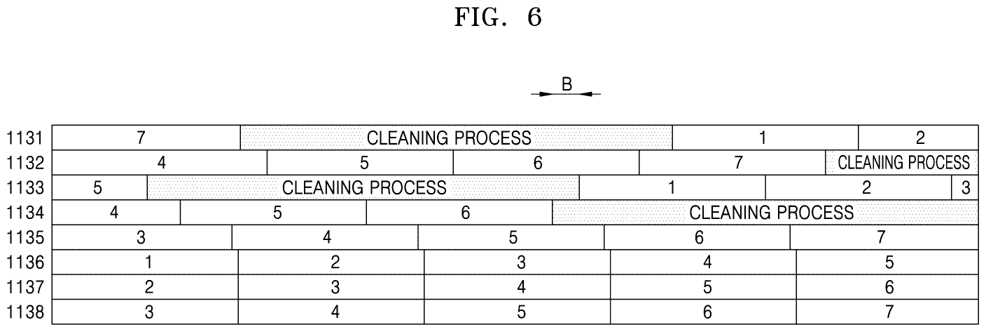

FIG. 3 is a block diagram of an embodiment of the controller 12, FIG. 4 is a flowchart showing an embodiment of a method of manufacturing a display apparatus, FIG. 5 is a view of an embodiment of an initial schedule ISC, and FIG. 6 is a view of an embodiment of a first modified schedule MSC1.

Referring to FIGS. 1 to 6, the controller 12 may include an initial scheduler 121, a determining portion 122, a modifier 123, and an executer 124.

First, referring to FIGS. 3 to 5, the initial scheduler 121 may generate an initial schedule ISC such that each of the plurality of deposition portions 113 performs a deposition process A times (A is a natural number) and then performs a cleaning process once.

In FIG. 5, a number written in a cell denotes the order of the deposition process. In addition, in FIG. 5, the horizontal length of a cell denotes the time desired for the deposition process or cleaning process to proceed. That is, referring to FIG. 5, an initial schedule ISC for first-1 to first-8 deposition portions 1131 to 1138 is known.

Although it is shown in FIG. 5 that the time desired for the cleaning process is longer than the second time desired for the deposition process, this is only one example and the time desired for the cleaning process and the time desired for the deposition process are not limited thereto. In addition, although it is shown in FIG. 5 that the times desired for the deposition processes of the plurality of deposition portions 113 are the same and the times desired for the cleaning processes of the plurality of deposition portions 113 are the same, this is only an example and the times desired for the cleaning processes may be different from the times desired for the deposition processes of the plurality of deposition portions 113.

In an embodiment, as shown in FIG. 5, A may be about 7. That is, on the initial schedule ISC, each of the first-1 to first-8 deposition portions 1131 to 1138 may perform a deposition process seven times and perform a cleaning process once.

When the initial scheduler 121 generates the initial schedule ISC, the determining portion 122 may determine whether the initial schedule ISC satisfies a first condition. Here, the first condition may be a condition that the number of deposition portions 113 simultaneously performing the cleaning process is about B or less (B is a natural number). In an embodiment, B may be about 2. That is, the determining portion 122 may determine whether the initial schedule ISC satisfies the first condition that the number of deposition portions 113 simultaneously performing the cleaning process is two or less.

In an embodiment, referring to the initial schedule ISC shown in FIG. 5, it is known that the first-2 deposition portion 1132, the first-3 deposition portion 1133, and the first-4 deposition portion 1134 simultaneously perform the cleaning process in a section A. That is, on the initial schedule ISC, it is known that the number of deposition portions 113 which simultaneously perform the cleaning process is three. Accordingly, the determining portion 122 may determine that the initial schedule ISC does not satisfy the first condition.

When the initial schedule ISC satisfies the first condition, the executer 124 may operate the plurality of deposition portions 113 based on the initial schedule ISC. In contrast, as shown in FIG. 5, when the initial schedule ISC does not satisfy the first condition, the modifier 123 may modify the initial schedule ISC to a first modified schedule MSC1.

Referring to FIGS. 3 to 6, when the initial schedule ISC does not satisfy the first condition, the modifier 123 may modify the initial schedule ISC to the first modified schedule MSC1.

Like FIG. 5, in FIG. 6, a number written in a cell denotes the order of the deposition process. In addition, in FIG. 6, the horizontal length of a cell denotes the time desired for the deposition process or cleaning process to proceed. That is, referring to FIG. 6, the first modified schedule MSC1 for the first-1 to first-8 deposition portions 1131 to 1138 is known.

When the initial schedule ISC does not satisfy the first condition, the modifier 123 may modify the initial schedule ISC to the first modified schedule MSC1 such that one of the plurality of deposition portions 113 simultaneously performing the cleaning process performs the deposition process (A-1) times and then performs the cleaning process once.

In addition, when the initial schedule ISC does not satisfy the first condition, the modifier 123 may modify the initial schedule ISC to the first modified schedule MSC1 such that another of the plurality of deposition portions 113 simultaneously performing the cleaning process performs the deposition process (A-2) times and then performs the cleaning process once.

In an embodiment, in the case where A is 7, when the initial schedule ISC does not satisfy the first condition, the modifier 123 may modify the initial schedule ISC to the first modified schedule MSC1 such that one of the plurality of deposition portions 113 performs the deposition process six times and then performs the cleaning process once, and another of the plurality of deposition portions 113 performs the deposition process five times and then performs the cleaning process once.

In an embodiment, as shown in FIGS. 5 and 6, because the initial schedule ISC does not satisfy the first condition, the modifier 123 may modify the initial schedule ISC to the first modified schedule MSC1 such that the first-4 deposition portion 1134 performs the deposition process six times and then performs the cleaning process once, and the first-3 deposition portion 1133 performs the deposition process five times and then performs the cleaning process once.

When the modifier 123 modifies the initial schedule ISC to the first modified schedule MSC1, the determining portion 122 may determine whether the first modified schedule MSC1 satisfies the first condition. In an embodiment, in the case where B is 2, the determining portion 122 may determine whether the first modified schedule MSC1 satisfies the first condition that the number of deposition portions 113 simultaneously performing the cleaning process is two or less.

In an embodiment, referring to the first modified schedule MSC1 shown in FIG. 6, it is known that the first-1 deposition portion 1131, the first-3 deposition portion 1133, and the first-4 deposition portion 1134 simultaneously perform the cleaning process in a section B. That is, on the first modified schedule MSC1, it is known that the number of deposition portions 113 which simultaneously perform the cleaning process is 3. Accordingly, the determining portion 122 may determine that the first modified schedule MSC1 does not satisfy the first condition.

When the first modified schedule MSC1 satisfies the first condition, the executer 124 may operate the plurality of deposition portions 113 based on the first modified schedule MSC1. In contrast, as shown in FIG. 6, when the first modified schedule MSC1 does not satisfy the first condition, the modifier 123 may modify the first modified schedule MSC1 to a second modified schedule MSC2.

When the first modified schedule MSC1 does not satisfy the first condition, the modifier 123 may modify the first modified schedule MSC1 to the second modified schedule MSC2 such that a cleaning process start timing of one of the plurality of deposition portions 113 simultaneously performing the cleaning process advances by one order.

In addition, when the first modified schedule MSC1 does not satisfy the first condition, the modifier 123 may modify the first modified schedule MSC1 to the second modified schedule MSC2 such that a cleaning process start timing of another of the plurality of deposition portions 113 simultaneously performing the cleaning process advances by two orders.

In an embodiment, as shown in FIG. 6, because the first modified schedule MSC1 does not satisfy the first condition, the modifier 123 may modify the first modified schedule MSC1 to the second modified schedule MSC2 such that the first-4 deposition portion 1134 performs the deposition process four times and then performs the cleaning process once, and the first-3 deposition portion 1133 performs the deposition process three times and then performs the cleaning process once.

When the modifier 123 modifies the first modified schedule MSC1 to the second modified schedule MSC2, the determining portion 122 may determine whether the second modified schedule MSC2 satisfies the first condition. In an embodiment, in the case where B is 2, the determining portion 122 may determine whether the second modified schedule MSC2 satisfies the first condition that the number of deposition portions 113 simultaneously performing the cleaning process is two or less.

When the second modified schedule MSC2 satisfies the first condition, the executer 124 may operate the plurality of deposition portions 113 based on the second modified schedule MSC2. In contrast, when the second modified schedule MSC2 does not satisfy the first condition, the modifier 123 may modify the second modified schedule MSC2 to a third modified schedule MSC3.

The above-described process may be repeated until the schedule modified by the modifier 123 satisfies the first condition. Consequently, the number of deposition portions 113 simultaneously performing the cleaning process may be B or less. In an embodiment, the number of deposition portions 113 simultaneously performing the cleaning process may be 2 or less.

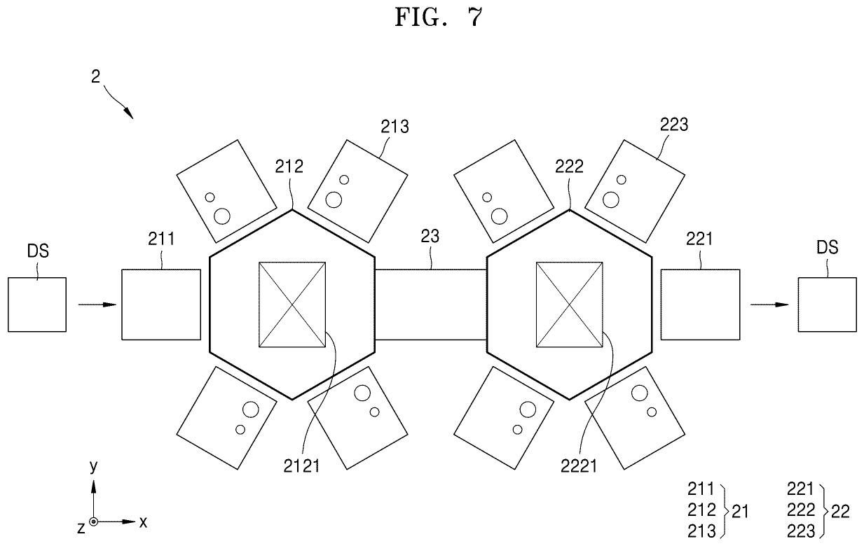

FIG. 7 is a schematic plan view of an embodiment of an apparatus 2 for manufacturing a display apparatus.

In FIG. 7, the same reference numerals as those of FIG. 1 denote the same members, and thus, repeated descriptions thereof are omitted.

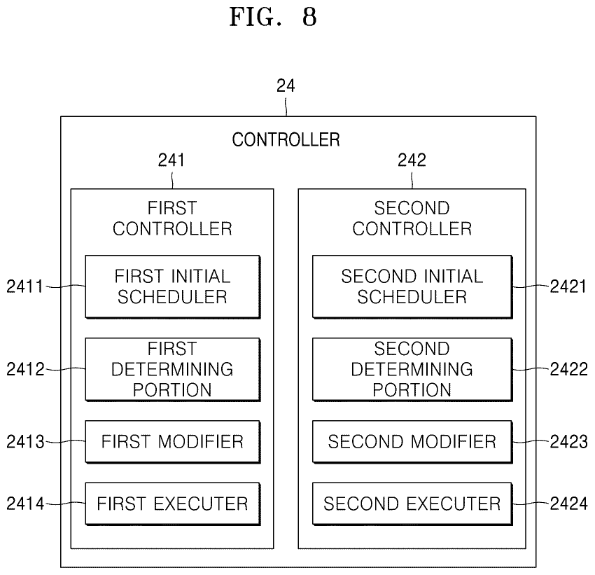

Referring to FIG. 7, the apparatus 2 for manufacturing a display apparatus may include a first process portion 21, a second process portion 22, a connector 23, and a controller (e.g., 24 in FIG. 8). Specifically, the first process portion 21 may include a first loading portion 211, a first carry portion 212, and a first deposition portion 213. The second process portion 22 may include a second loading portion 221, a second carry portion 222, and a second deposition portion 223.

The first loading portion 211 may serve as an entry of the apparatus 2 for manufacturing a display apparatus, and a display substrate DS may be loaded into the first loading portion 211 from the outside. The first loading portion 211 may be connected to the first carry portion 212. The display substrate DS may be transferred to the first carry portion 212 through the first loading portion 211.

The inner pressure of the first loading portion 211 may be adjusted to be equal or similar to atmospheric pressure. In an alternative embodiment, the inner pressure of the first loading portion 211 may be adjusted to be equal or similar to a vacuum state. In an embodiment, when the display substrate DS is loaded from the outside, the pressure of the first loading portion 211 may be adjusted to be equal or similar to atmospheric pressure. In addition, when the display substrate DS is transferred to the first carry portion 212, the pressure of the first loading portion 211 may be adjusted to be equal or similar to a vacuum state.

The first carry portion 212 may be connected to the first loading portion 211 and the first deposition portion 213. The first carry portion 212 may receive or transfer the display substrate DS from the first deposition portion 213 or the first loading portion 211. In this case, the first carry portion 212 may include a first robot arm 2121. The first robot arm 2121 may transfer the display substrate DS from the first loading portion 211 to the first carry portion 212. In addition, the first robot arm 2121 may transfer the display substrate DS from the first carry portion 212 to the first deposition portion 213, or transfer a process-completed display substrate DS from the first deposition portion 213 to the first carry portion 212.

The first deposition portion 213 may perform a deposition process and a cleaning process. The deposition process may be a process of depositing a deposition material on the display substrate DS. The cleaning process may be a process of cleaning the inside of the first deposition portion 213. The first deposition portion 213 may be provided in plural. In an embodiment, five first deposition portions 213 may be provided. The first deposition portion 213 may be connected to the first carry portion 212. That is, each of the plurality of first deposition portions 213 may be connected to the first carry portion 212.

In an embodiment, four first deposition portions 213 may be provided. The plurality of first deposition portions 213 may surround the first carry portion 212 and be arranged along a circumferential direction. The plurality of first deposition portions 213 may be arranged within the radius range of the first robot arm 2121. However, this is provided as one of embodiments and the number and arrangement of the first deposition portions 213 are not limited thereto.

The second loading portion 221 may serve as an entry of the apparatus 2 for manufacturing a display apparatus, and a display substrate DS may be carried to the outside from the second loading portion 221. The second loading portion 221 may be connected to the second carry portion 222. The display substrate DS may be transferred to the second loading portion 221 through the second carry portion 222.

The inner pressure of the second loading portion 221 may be adjusted to be equal or similar to atmospheric pressure. In an alternative embodiment, the inner pressure of the second loading portion 221 may be adjusted to be equal or similar to a vacuum state. In an embodiment, when the display substrate DS is carried to the outside from the second loading portion 221, the pressure of the second loading portion 221 may be adjusted to be equal or similar to atmospheric pressure. In addition, when the display substrate DS is transferred from the second carry portion 222 to the second loading portion 221, the pressure of the second loading portion 221 may be adjusted to be equal or similar to a vacuum state.

The second carry portion 222 may be connected to the second loading portion 221 and the second deposition portion 223. The second carry portion 222 may receive or transfer the display substrate DS from the second deposition portion 223 or the second loading portion 221. In this case, the second carry portion 222 may include a second robot arm 2221. The second robot arm 2221 may transfer the display substrate DS from the second loading portion 221 to the second carry portion 222. In addition, the second robot arm 2221 may transfer the display substrate DS from the second carry portion 222 to the second deposition portion 223, or transfer a process-completed display substrate DS from the second deposition portion 223 to the second carry portion 222.

The second deposition portion 223 may perform a deposition process and a cleaning process. The deposition process may be a process of depositing a deposition material on the display substrate DS. The cleaning process may be a process of cleaning the inside of the second deposition portion 223. The second deposition portion 223 may be provided in plural. In an embodiment, five second deposition portions 223 may be provided. The second deposition portion 223 may be connected to the second carry portion 222. That is, each of the plurality of second deposition portions 223 may be connected to the second carry portion 222.

In an embodiment, four second deposition portions 223 may be provided. The plurality of second deposition portions 223 may surround the second carry portion 222 and be arranged along a circumferential direction. The plurality of second deposition portions 223 may be arranged within the radius range of the second robot arm 2221. However, this is provided as one of embodiments and the number and arrangement of the second deposition portions 223 are not limited thereto.

The connector 23 may connect the first process portion 21 to the second process portion 22. The connector 23 may serve as a passage connecting the first process portion 21 to the second process portion 22. The display substrate DS may be transferred from the first process portion 21 to the second process portion 22 through the connector 23.

The controller may control the process portion. In an embodiment, the controller may control each of the plurality of first deposition portions 213 and the plurality of second deposition portions 223. The controller is described below in detail with reference to FIGS. 8 to 10.

The plurality of first deposition portions 213 and the plurality of second deposition portions 223 may perform the same deposition process. A deposition material may be deposited on the display substrate DS by one of the plurality of first deposition portions 213 and the plurality of second deposition portions 223.

A process in which the deposition material is deposited on the display substrate DS is described. The display substrate DS may be loaded to the first loading portion 211 from the outside. The display substrate DS loaded into the first loading portion 211 may be transferred to the first carry portion 212. The first carry portion 212 may transfer the display substrate DS to one of the plurality of first deposition portions 213. When the deposition process of the display substrate DS is completed at one of the plurality of first deposition portions 213, the first carry portion 212 may receive the display substrate DS again. The deposition process-completed display substrate DS may sequentially pass through the connector 23, the second carry portion 222, and the second loading portion 221 and then be carried to the outside.

In an alternative embodiment, the display substrate DS may be loaded from the outside to the first loading portion 211, may sequentially pass through the first carry portion 212 and the connector 23, and then be transferred to the second carry portion 222. The second carry portion 222 may transfer the display substrate DS to one of the plurality of second deposition portions 223. When the deposition process of the display substrate DS is completed at one of the plurality of second deposition portions 223, the second carry portion 222 may receive the display substrate DS again. The deposition process-completed display substrate DS may be carried to the outside through the second loading portion 221.

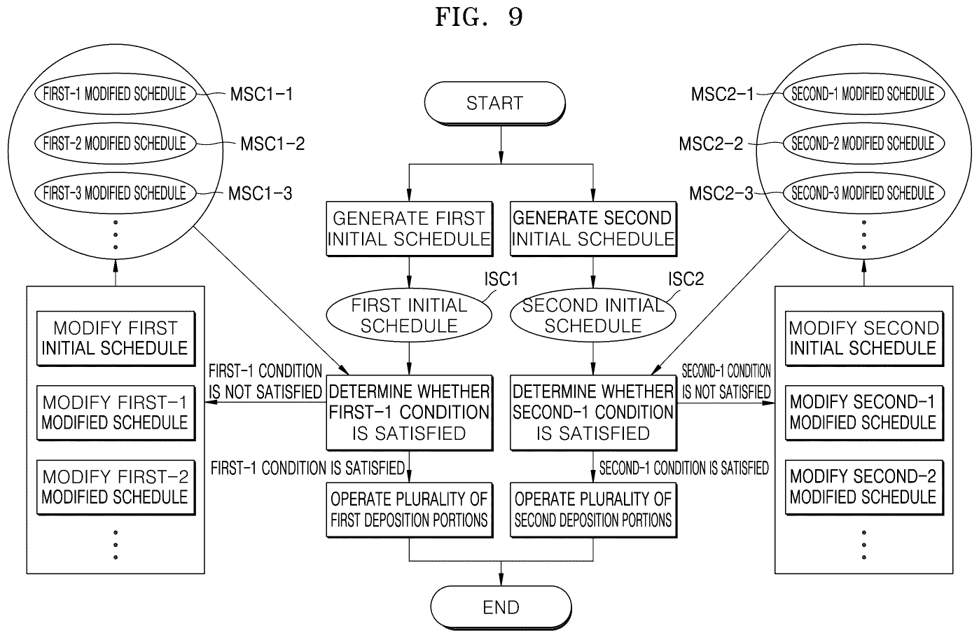

FIG. 8 is a block diagram of an embodiment of a controller 24, and FIG. 9 is a flowchart showing an embodiment of a method of manufacturing a display apparatus.

In FIGS. 8 and 9, the same reference numerals as those of FIGS. 1 to 7 denote the same members, and thus, repeated descriptions thereof are omitted.

Referring to FIGS. 7 to 9, the controller 24 may include a first controller 241 and a second controller 242. Specifically, the first controller 241 may control the first process portion 21, and the second controller 242 may control the second process portion 22.

The first controller 241 may include a first initial scheduler 2411, a first determining portion 2412, a first modifier 2413, and a first executer 2414.

The first initial scheduler 2411 may generate a first initial schedule ISC1 such that each of the plurality of first deposition portions 213 performs a deposition process A times (A is a natural number) and then performs a cleaning process once.

In an embodiment, A may be about 7. That is, on the first initial schedule ISC1, each of the plurality of first deposition portions 213 may perform a deposition process seven times and perform a cleaning process once.

When the first initial scheduler 2411 generates the first initial schedule ISC1, the first determining portion 2412 may determine whether the first initial schedule ISC1 satisfies a first-1 condition. Here, the first-1 condition may be a condition that the number of first deposition portions 213 simultaneously performing the cleaning process is B or less (B is a natural number). In an embodiment, B may be about 1. That is, the first determining portion 2412 may determine whether the first initial schedule ISC1 satisfies the first-1 condition that the number of first deposition portions 213 simultaneously performing the cleaning process is 1 or less.

When the first initial schedule ISC1 satisfies the first-1 condition, the first executer 2414 may operate the plurality of first deposition portions 213 based on the first initial schedule ISC1. In contrast, when the first initial schedule ISC1 does not satisfy the first-1 condition, the first modifier 2413 may modify the first initial schedule ISC1 to a first-1 modified schedule MSC1-1.

When the first initial schedule ISC1 does not satisfy the first-1 condition, the first modifier 2413 may modify the first initial schedule ISC1 to the first-1 modified schedule MSC1-1 such that one of the plurality of first deposition portions 213 simultaneously performing the cleaning process performs the deposition process (A-1) times and then performs the cleaning process once.

In addition, when the first initial schedule ISC1 does not satisfy the first-1 condition, the first modifier 2413 may modify the first initial schedule ISC1 to the first-1 modified schedule MSC1-1 such that another of the plurality of first deposition portions 213 simultaneously performing the cleaning process performs the deposition process (A-2) times and then performs the cleaning process once.

In an embodiment, in the case where A is 7, when the first initial schedule ISC1 does not satisfy the first-1 condition, the first modifier 2413 may modify the first initial schedule ISC1 to the first-1 modified schedule MSC1-1 such that one of the plurality of first deposition portions 213 performs the deposition process six times and then performs the cleaning process once, and another of the plurality of first deposition portions 213 performs the deposition process five times and then performs the cleaning process once.

When the first modifier 2413 modifies the first initial schedule ISC1 to the first-1 modified schedule MSC1-1, the first determining portion 2412 may determine whether the first-1 modified schedule MSC1-1 satisfies the first-1 condition. In an embodiment, in the case where B is 1, the first determining portion 2412 may determine whether the first-1 modified schedule MSC1-1 satisfies the first-1 condition that the number of first deposition portions 213 simultaneously performing the cleaning process is one or less.

When the first-1 modified schedule MSC1-1 satisfies the first-1 condition, the first executer 2414 may operate the plurality of first deposition portions 213 based on the first-1 modified schedule MSC1-1. In contrast, when the first-1 modified schedule MSC1-1 does not satisfy the first-1 condition, the first modifier 2413 may modify the first-1 modified schedule MSC1-1 to a first-2 modified schedule MSC1-2.

When the first-1 modified schedule MSC1-1 does not satisfy the first-1 condition, the first modifier 2413 may modify the first-1 modified schedule MSC1-1 to the first-2 modified schedule MSC1-2 such that a cleaning process start timing of one of the plurality of first deposition portions 213 simultaneously performing the cleaning process advances by one order.

In addition, when the first-1 modified schedule MSC1-1 does not satisfy the first-1 condition, the first modifier 2413 may modify the first-1 modified schedule MSC1-1 to the first-2 modified schedule MSC1-2 such that a cleaning process start timing of another of the plurality of first deposition portions 213 simultaneously performing the cleaning process advances by two orders.

When the first modifier 2413 modifies the first-1 modified schedule MSC1-1 to the first-2 modified schedule MSC1-2, the first determining portion 2412 may determine whether the first-2 modified schedule MSC1-2 satisfies the first-1 condition. In an embodiment, in the case where B is 1, the first determining portion 2412 may determine whether the first-2 modified schedule MSC1-2 satisfies the first-1 condition that the number of first deposition portions 213 simultaneously performing the cleaning process is one or less.

When the first-2 modified schedule MSC1-2 satisfies the first-1 condition, the first executer 2414 may operate the plurality of first deposition portions 213 based on the first-2 modified schedule MSC1-2. In contrast, when the first-2 modified schedule MSC1-2 does not satisfy the first-1 condition, the first modifier 2413 may modify the first-2 modified schedule MSC1-2 to a first-3 modified schedule MSC1-3.

The above-described process may be repeated until the schedule modified by the first modifier 2413 satisfies the first-1 condition. Consequently, the number of first deposition portions 213 simultaneously performing the cleaning process may be B or less. In an embodiment, the number of first deposition portions 213 simultaneously performing the cleaning process may be 1 or less.

The second controller 242 may include a second initial scheduler 2421, a second determining portion 2422, a second modifier 2423, and a second executer 2424.

The second initial scheduler 2421 may generate a second initial schedule ISC2 such that each of the plurality of second deposition portions 223 performs a deposition process A times (A is a natural number) and then performs a cleaning process once.

In an embodiment, A may be about 7. That is, on the second initial schedule ISC2, each of the plurality of second deposition portions 223 may perform a deposition process seven times and perform a cleaning process once.

When the second initial scheduler 2421 generates the second initial schedule ISC2, the second determining portion 2422 may determine whether the second initial schedule ISC2 satisfies a second-1 condition. Here, the second-1 condition may be a condition that the number of second deposition portions 223 simultaneously performing the cleaning process is B or less (B is a natural number). In an embodiment, B may be about 1. That is, the second determining portion 2422 may determine whether the second initial schedule ISC2 satisfies the second-1 condition that the number of second deposition portions 223 simultaneously performing the cleaning process is 1 or less.

When the second initial schedule ISC2 satisfies the second-1 condition, the second executer 2424 may operate the plurality of second deposition portions 223 based on the second initial schedule ISC2. In contrast, when the second initial schedule ISC2 does not satisfy the second-1 condition, the second modifier 2423 may modify the second initial schedule ISC2 to a second-1 modified schedule MSC2-1.

When the second initial schedule ISC2 does not satisfy the second-1 condition, the second modifier 2423 may modify the second initial schedule ISC2 to the second-1 modified schedule MSC2-1 such that one of the plurality of second deposition portions 223 simultaneously performing the cleaning process performs the deposition process (A-1) times and then performs the cleaning process once.

In addition, when the second initial schedule ISC2 does not satisfy the second-1 condition, the second modifier 2423 may modify the second initial schedule ISC2 to the second-1 modified schedule MSC2-1 such that another of the plurality of second deposition portions 223 simultaneously performing the cleaning process performs the deposition process (A-2) times and then performs the cleaning process once.

In an embodiment, in the case where A is 7, when the second initial schedule ISC2 does not satisfy the second-1 condition, the second modifier 2423 may modify the second initial schedule ISC2 to the second-1 modified schedule MSC2-1 such that one of the plurality of second deposition portions 223 performs the deposition process six times and then performs the cleaning process once, and another of the plurality of second deposition portions 223 performs the deposition process five times and then performs the cleaning process once.

When the second modifier 2423 modifies the second initial schedule ISC2 to the second-1 modified schedule MSC2-1, the second determining portion 2422 may determine whether the second-1 modified schedule MSC2-1 satisfies the second-1 condition. In an embodiment, in the case where b is 1, the second determining portion 2422 may determine whether the second-1 modified schedule MSC2-1 satisfies the second-1 condition that the number of second deposition portions 223 simultaneously performing the cleaning process is one or less.

When the second-1 modified schedule MSC2-1 satisfies the second-1 condition, the second executer 2424 may operate the plurality of second deposition portions 223 based on the second-1 modified schedule MSC2-1. In contrast, when the second-1 modified schedule MSC2-1 does not satisfy the second-1 condition, the second modifier 2423 may modify the second-1 modified schedule MSC2-1 to a second-2 modified schedule MSC2-2.

When the second-1 modified schedule MSC2-1 does not satisfy the second-1 condition, the second modifier 2423 may modify the second-1 modified schedule MSC2-1 to the second-2 modified schedule MSC2-2 such that a cleaning process start timing of one of the plurality of second deposition portions 223 simultaneously performing the cleaning process advances by one order.

In addition, when the second-1 modified schedule MSC2-1 does not satisfy the second-1 condition, the second modifier 2423 may modify the second-1 modified schedule MSC2-1 to the second-2 modified schedule MSC2-2 such that a cleaning process start timing of another of the plurality of second deposition portions 223 simultaneously performing the cleaning process advances by two orders.

When the second modifier 2423 modifies the second-1 modified schedule MSC2-1 to the second-2 modified schedule MSC2-2, the second determining portion 2422 may determine whether the second-2 modified schedule MSC2-2 satisfies the second-1 condition. In an embodiment, in the case where b is 1, the second determining portion 2422 may determine whether the second-2 modified schedule MSC2-2 satisfies the second-1 condition that the number of second deposition portions 223 simultaneously performing the cleaning process is one or less.

When the second-2 modified schedule MSC2-2 satisfies the second-1 condition, the second executer 2424 may operate the plurality of second deposition portions 223 based on the second-2 modified schedule MSC2-2. In contrast, when the second-2 modified schedule MSC2-2 does not satisfy the second-1 condition, the second modifier 2423 may modify the second-2 modified schedule MSC2-2 to a second-3 modified schedule MSC2-3.

The above-described process may be repeated until the schedule modified by the second modifier 2423 satisfies the second-1 condition. Consequently, the number of second deposition portions 223 simultaneously performing the cleaning process may be B or less. In an embodiment, the number of second deposition portions 223 simultaneously performing the cleaning process may be 1 or less.

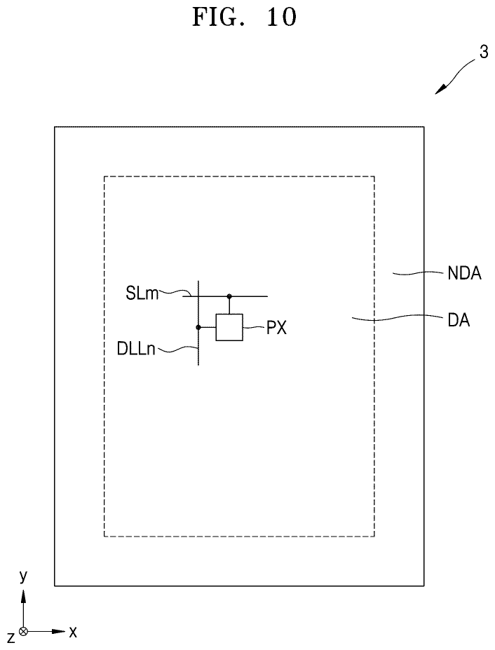

FIG. 10 is a schematic plan view of a display apparatus 3 in an embodiment, and FIG. 11 is a schematic cross-sectional view of the display apparatus 3.

Referring to FIG. 10, the display apparatus 3 may include a display area DA and a non-display area NDA surrounding the display area DA. In an embodiment, a pixel PX may be connected to a scan line SLm and a data line DLLn, where m and n are natural numbers. In an embodiment, the scan line SLm may extend in a first direction x and the data line DLLn may extend in a second direction y crossing the first direction x. Referring to FIGS. 10 and 11, the display apparatus 3 may include a display substrate S. The display substrate S may include the substrate 100 and layers in the display layer DL other than an emission layer 2222 and a common electrode 2223.

The display layer DL and a thin-film encapsulation layer TFE may be disposed on the substrate 100 in a third direction z crossing a plane defined by the scan line SLm and data line DLLn. The display layer DL may include a pixel circuit layer PCL and a display element layer DEL.

The substrate 100 may include glass or polymer resin such as polyethersulfone, polyarylate, polyetherimide, polyethylene naphthalate, polyethylene terephthalate, polyphenylene sulfide, polyimide, polycarbonate, cellulose tri acetate, cellulose acetate propionate, or the like.

A barrier layer (not shown) may be further disposed between the display layer DL and the substrate 100. The barrier layer may prevent penetration of external foreign substances and may be a single layer or a multi-layer including silicon nitride (SiNₓ, x>0), and silicon oxide (SiOₓ, x>0).

The pixel circuit layer PCL may be disposed on the substrate 100. The pixel circuit layer PCL may include a thin-film transistor TFT, a buffer layer 1111, a first insulating layer 13a, a second insulating layer 13b, a third insulating layer 15, and a planarization layer 17 under and/or on elements of the thin-film transistor TFT.

The buffer layer 1111 may include an inorganic insulating material such as silicon nitride, silicon oxynitride, and silicon oxide, and include a single layer or a multi- layer including the above inorganic insulating materials.

The thin-film transistor TFT may include a semiconductor layer 127, and the semiconductor layer 127 may include polycrystalline silicon. In an alternative embodiment, the semiconductor layer 127 may include amorphous silicon, an oxide semiconductor, or an organic semiconductor. The semiconductor layer 127 may include a channel region 12c, a drain region 12a, and a source region 12b, the drain region 12a and the source region 12b being respectively on two opposite sides of the channel region 12c. A gate electrode 14 may overlap the channel region 12c.

The gate electrode 14 may include a low-resistance metal material. The gate electrode 14 may include a conductive material including molybdenum (Mo), aluminum (Al), copper (Cu), and titanium (Ti) and have a single-layered structure or a multi-layered structure including the above materials.

The first insulating layer 13a between the semiconductor layer 127 and the gate electrode 14 may include an inorganic insulating material including silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ).

The second insulating layer 13b may cover the gate electrode 14. Similar to the first insulating layer 13a, the second insulating layer 13b may include an inorganic insulating material including silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂).

An upper electrode Cst2 of a storage capacitor Cst may be disposed on the second insulating layer 13b. The upper electrode Cst2 may overlap the gate electrode 14 therebelow. In this case, the gate electrode 14 and the upper electrode Cst2 overlapping each other with the second insulating layer 13b therebetween may constitute the storage capacitor Cst. That is, the gate electrode 14 may serve as a lower electrode Cst1 of the storage capacitor Cst.

As described above, the storage capacitor Cst may overlap the thin-film transistor TFT. In an embodiment, the storage capacitor Cst may be formed not to overlap the thin-film transistor TFT.

The upper electrode Cst2 may include aluminum (Al), platinum (Pt), palladium (Pd), silver (Ag), magnesium (Mg), gold (Au), nickel (Ni), neodymium (Nd), iridium (Ir), chrome (Cr), calcium (Ca), molybdenum (Mo), titanium (Ti), tungsten (W), and/or copper (Cu), and include a single layer or a multi-layer including the above materials.

The third insulating layer 15 may cover the upper electrode Cst2. The third insulating layer 15 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). The third insulating layer 15 may include a single layer or a multi-layer including the inorganic insulating material.

A drain electrode 16a and a source electrode 16b may each be disposed on the third insulating layer 15. The drain electrode 16a and the source electrode 16b may each include a material having a relatively high conductivity. The drain electrode 16a and the source electrode 16b may each include a conductive material including molybdenum (Mo), aluminum (Al), copper (Cu), and titanium (Ti) and include a single layer or a multi-layer including the above materials. In an embodiment, the drain electrode 16a and the source electrode 16b may each have a multi-layered structure of Ti/Al/Ti.

The planarization layer 17 may include an organic insulating material. The planarization layer 17 may include an organic insulating material including a general-purpose polymer such as polymethylmethacrylate (“PMMA”) or polystyrene (“PS”), polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, or any combinations thereof.

The display element layer DEL may be disposed on the pixel circuit layer PCL having the above structure. The display element layer DEL may include an organic light-emitting diode OLED, and a pixel electrode 2221 of the organic light-emitting diode OLED may be electrically connected to the thin-film transistor TFT through a contact hole defined in the planarization layer 17.

A pixel PX may include the organic light-emitting diode OLED and the thin-film transistor TFT. Each pixel PX may emit red, green, or blue light, or emit red, green, blue, or white light by the organic light-emitting diode OLED, for example.

The pixel electrode 2221 may include a conductive oxide such as indium tin oxide (“ITO”), indium zinc oxide (“IZO”), zinc oxide (ZnO), indium oxide (In₂O₃), indium gallium oxide (“IGO”), or aluminum zinc oxide (“AZO”). In another embodiment, the pixel electrode 2221 may include a reflective layer including silver (Ag), magnesium (Mg), aluminum (Al), platinum (Pt), palladium (Pd), gold (Au), nickel (Ni), neodymium (Nd), iridium (Ir), chrome (Cr), or any combinations thereof. In another embodiment, the pixel electrode 2221 may further include a layer on/under the reflective layer, the layer including ITO, IZO, ZnO, or In₂O₃.

A pixel-defining layer 19 may be disposed on the pixel electrode 2221. The pixel-defining layer 19 defines an opening 19OP exposing the central portion of the pixel electrode 2221. The pixel-defining layer 19 may include an organic insulating material and/or an inorganic insulating material. The opening 19OP may define an emission area EA of light emitted from the organic light-emitting diode OLED. In an embodiment, the width of the opening 19OP may correspond to the width of the emission area EA.

The emission layer 2222 may be disposed in the opening 19OP of the pixel- defining layer 19. The emission layer 2222 may include a polymer organic material or a low-molecular weight organic material which emits light having a preset color. In another embodiment, the emission layer 2222 may include a quantum-dot material. The emission layer 2222 may be formed by discharging liquid droplets using the apparatus for manufacturing the display apparatus.

Although not shown, a first functional layer and a second functional layer may be respectively disposed under and on the emission layer 2222. The first functional layer may include a hole transport layer (“HTL”), or include an HTL and a hole injection layer (“HIL”), for example. The second functional layer is an element disposed on the emission layer 2222 and is optional. The second functional layer may include an electron transport layer (“ETL”) and/or an electron injection layer (“EIL”). Like a common electrode 2223 described below, the first functional layer and/or the second functional layer may be common layers covering an entirety of the substrate 100.

The common electrode 2223 may include a conductive material having a relatively low work function. In an embodiment, the common electrode 2223 may include a (semi) transparent layer including silver (Ag), magnesium (Mg), aluminum (Al), platinum (Pt), palladium (Pd), gold (Au), nickel (Ni), neodymium (Nd), iridium (Ir), chrome (Cr), or any alloys thereof. In an alternative embodiment, the common electrode 2223 may further include a layer on the (semi) transparent layer, the layer including ITO, IZO, ZnO, or In₂O₃.

The thin-film encapsulation layer TFE may be disposed on the common electrode 2223. In an embodiment, the thin-film encapsulation layer TFE may include at least one inorganic encapsulation layer and at least one organic encapsulation layer. In an embodiment, it is shown in FIG. 11 that the thin-film encapsulation layer TFE includes a first inorganic encapsulation layer 31, an organic encapsulation layer 32, and a second inorganic encapsulation layer 33 that are sequentially stacked.

The first inorganic encapsulation layer 31 and the second inorganic encapsulation layer 33 may include at least one inorganic material from among aluminum oxide, titanium oxide, tantalum oxide, hafnium oxide, zinc oxide, silicon oxide, silicon nitride, and silicon oxynitride. The organic encapsulation layer 32 may include a polymer-based material. The polymer-based material may include an acryl-based resin, an epoxy-based resin, polyimide, and polyethylene. In an embodiment, the organic encapsulation layer 32 may include acrylate.

In another embodiment, the thin-film encapsulation layer TFE may have a structure in which an inner space between the substrate 100 and the upper substrate is encapsulated. The substrate 100 and an upper substrate, which is a transparent member, are coupled to each other using a sealing member. In this case, a moisture absorbent or a filler may be disposed in the inner space. The sealing member may be sealant. In another embodiment, the sealing member may include a material cured by a laser beam. In an embodiment, the sealing member may include frit. Specifically, the sealing member may include an organic sealant such as a urethane-based resin, an epoxy-based resin, an acrylic resin, or silicone which is an inorganic sealant. As a urethane-based resin, e.g., urethane acrylate or the like may be used. As acrylic resin, e.g., butyl acrylate, ethylhexyl acrylate, or the like may be used. The sealing member may include a material cured by heat.

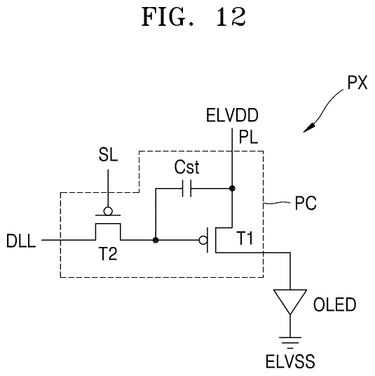

FIG. 12 is an equivalent circuit diagram of an embodiment of a pixel PX of a display apparatus.

Each pixel PX may include a pixel circuit PC and a display element connected to the pixel circuit PC. The display element may be an organic light-emitting diode OLED, for example. The pixel circuit PC may include a first thin-film transistor T1, a second thin-film transistor T2, and a storage capacitor Cst. Each pixel PX may emit, e.g., red, green, blue, or white light from the organic light-emitting diode OLED.

The second thin-film transistor T2 is a switching thin-film transistor, may be connected to a scan line SL and a data line DLL, and may transfer a data voltage to the first thin-film transistor T1 based on a switching voltage, the data voltage being input from the data line DLL, and the switching voltage being input from the scan line SL. The storage capacitor Cst may be connected to the second thin-film transistor T2 and a driving voltage line PL, and may store a voltage corresponding to a difference between a voltage transferred from the second thin-film transistor T2 and a first power voltage ELVDD supplied to the driving voltage line PL.

The first thin-film transistor T1 is a driving thin-film transistor, may be connected to the driving voltage line PL and the storage capacitor Cst, and may control a driving current according to the voltage stored in the storage capacitor Cst, the driving current flowing from the driving voltage line PL to the organic light-emitting diode OLED. The organic light-emitting diode OLED may emit light having a preset brightness corresponding to the driving current. An opposite electrode (e.g., a cathode) of the organic light-emitting diode OLED may receive a second power voltage ELVSS.

Although it is described with reference to FIG. 12 that the pixel circuit PC includes two thin-film transistors and one storage capacitor, the disclosure is not limited thereto. The number of thin-film transistors and the number of storage capacitors may be variously changed according to the design of the pixel circuit PC. In an embodiment, the pixel circuit PC may further include four or more thin-film transistors as well as the two thin-film transistors.

By embodiments, the efficiency of the apparatus for manufacturing the display apparatus may be improved.

Effects of the disclosure are not limited to the above mentioned effects and other effects not mentioned may be clearly understood by those of ordinary skill in the art from the following claims.

It should be understood that embodiments described herein should be considered in a descriptive sense only and not for purposes of limitation. Descriptions of features or advantages within each embodiment should typically be considered as available for other similar features or advantages in other embodiments. While embodiments have been described with reference to the drawing figures, it will be understood by those of ordinary skill in the art that various changes in form and details may be made therein without departing from the spirit and scope as defined by the following claims.

What is claimed is:

1. An apparatus for manufacturing a display apparatus, the apparatus comprising:
a process portion including a plurality of deposition portions which perform a deposition process of depositing a deposition material on a display substrate, and a cleaning process of cleaning an inside of the plurality of deposition portions; and
a controller which controls the process portion, the controller including:
an initial scheduler which generates an initial schedule so that each of the plurality of deposition portions performs the deposition process A times, A being a natural number, and then performs the cleaning process once;
a determining portion which determines whether the initial schedule satisfies a first condition which a number of deposition portions simultaneously performing the cleaning process is B or less, B being a natural number;
an executer which operates the plurality of deposition portions based on the initial schedule in response to a case in which the initial schedule satisfies the first condition; and
a modifier which modifies the initial schedule to a first modified schedule, in response to a case in which the initial schedule does not satisfy the first condition, so that one of the plurality of deposition portions simultaneously performing the cleaning process performs the deposition process (A-1) times and then performs the cleaning process once.

2. The apparatus of claim 1, wherein the determining portion determines whether the first modified schedule satisfies the first condition, and the executer operates the plurality of deposition portions based on the first modified schedule, in response to a case in which the first modified schedule satisfies the first condition.

3. The apparatus of claim 1, wherein the modifier modifies the initial schedule to the first modified schedule, in response to the case in which the initial schedule does not satisfy the first condition, so that another of the plurality of deposition portions simultaneously performing the cleaning process performs the deposition process (A-2) times and then performs the cleaning process once.

4. The apparatus of claim 1, wherein A is about 7.

5. The apparatus of claim 1, wherein B is about 2.

6. The apparatus of claim 1, wherein the plurality of deposition portions is provided as eight.

7. An apparatus for manufacturing a display apparatus, the apparatus comprising:
a first process portion including a plurality of first deposition portions which perform a deposition process of depositing a deposition material on a display substrate, and a cleaning process of cleaning an inside;
a second process portion including a plurality of second deposition portions which perform the deposition process of the depositing the deposition material on the display substrate, and the cleaning process of the cleaning the inside; and
a controller including:
a first controller which controls the first process portion, the first controller including:
a first initial scheduler which generates a first initial schedule so that each of the plurality of first deposition portions performs the deposition process A times, A being a natural number, and then performs the cleaning process once;
a first determining portion which determines whether the first initial schedule satisfies a first-1 condition which a number of first deposition portions simultaneously performing the cleaning process is B or less, B being a natural number;
a first executer which operates the plurality of first deposition portions based on the first initial schedule in response to a case in which the first initial schedule satisfies the first-1 condition; and
a first modifier which modifies the first initial schedule to a first-1 modified schedule, in response to a case in which the first initial schedule does not satisfy the first-1 condition, so that one of the plurality of first deposition portions simultaneously performing the cleaning process performs the deposition process (A-1) times and then performs the cleaning process once; and
a second controller which controls the second process portion.

8. The apparatus of claim 7, wherein the first determining portion determines whether the first-1 modified schedule satisfies the first-1 condition, and the first executer operates the plurality of first deposition portions based on the first-1 modified schedule in response to a case in which the first-1 modified schedule satisfies the first-1 condition.

9. The apparatus of claim 7, wherein A is about 7.

10. The apparatus of claim 7, wherein B is about 1.

11. The apparatus of claim 7, wherein the plurality of first deposition portions is provided as five.

12. The apparatus of claim 7, wherein the second controller includes:
a second initial scheduler which generates a second initial schedule so that each of the plurality of second deposition portions performs the deposition process A times, A being a natural number, and then performs the cleaning process once;
a second determining portion which determines whether the second initial schedule satisfies a first-2 condition which a number of second deposition portions simultaneously performing the cleaning process is B or less (B is a natural number);
a second executer which operates the plurality of second deposition portions based on the second initial schedule in response to a case in which the second initial schedule satisfies the first-2 condition; and
a second modifier which modifies the second initial schedule to a second-1 modified schedule, in response to a case in which the second initial schedule does not satisfy the first-2 condition, so that one of the plurality of second deposition portions simultaneously performing the cleaning process performs the deposition process (A-1) times and then performs the cleaning process once.

13. The apparatus of claim 12, wherein the second determining portion determines whether the second-1 modified schedule satisfies the first-2 condition, and the second executer operates the plurality of second deposition portions based on the second-1 modified schedule in response to a case in which the second-1 modified schedule satisfies the first-1 condition.

14. The apparatus of claim 12, wherein the plurality of second deposition portions is provided as five.

15. The apparatus of claim 7, wherein the deposition process of the display substrate is performed by one of the plurality of first deposition portions and the plurality of second deposition portions.
